(19) United States
(12) Patent Application Publication
(10) Pub. No.: US 2025/0393325 A1
(43) Pub. Date: Dec. 25, 2025

(54) ELECTRONIC DEVICE

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 19/241,933

(22) Filed: Jun. 18, 2025

(30) Foreign Application Priority Data
Jun. 21, 2024 (FR) FR2406705

(51) Int. Cl. H10F 39/00; B82Y 20/00; G02B 5/28; H10F 39/18

(52) U.S. Cl. CPC H10F 39/8067; G02B 5/281; H10F 39/1825; H10F 39/8053; H10F 39/807; B82Y 20/00

(57) ABSTRACT

An electronic device includes a first pixel having a single junction and a second pixel having a heterojunction formed by a semiconductor substrate layer in contact with a quantum dot layer. A first filter of a first color, configured to let through wavelengths of the first color and infrared, is arranged vertically in line with the first pixel and at least partially vertically in line with the second pixel. An optical element is interposed between the first filter and the second pixel. The first filter and the optical element operate so that the first pixel receives wavelengths of the first color and the second pixel only receives infrared wavelengths.

### PRIORITY CLAIM

This application claims the priority benefit of French Application for Patent No. FR2406705, filed on Jun. 21, 2024, the content of which is hereby incorporated by reference in its entirety to the maximum extent allowable by law.

### TECHNICAL FIELD

The present disclosure generally concerns electronic devices and, more specifically, optoelectronic devices comprising photodiodes, as well as associated methods for manufacturing such electronic devices.

### BACKGROUND

A photodiode is a semiconductor component having the ability to capture a radiation in the optical field and to transform it into an electrical signal.

In a common type of photodiodes, the space charge region is located in a semiconductor material, generally silicon. However, silicon is not very reactive at near-infrared (NIR) and short-wave infrared (SWIR) wavelengths.

There exists a need to provide devices sensitive both to wavelengths in the visible range and to infrared wavelengths.

There is a need to overcomes all or part of the disadvantages of known devices.

### SUMMARY

In an embodiment, an electronic device comprises: at least one first pixel having a single junction; at least one second pixel comprising a heterojunction based on quantum dots; at least one first filter of a first color configured for only letting through wavelengths of said first color and infrared, said at least one first filter arranged vertically in line with the first pixel and at least partially in line with the second pixel; and an optical element interposed between the first filter and the second pixel; wherein the first filter and the optical element are configured so that the first pixel receives wavelengths of said first color and the second pixel only receives infrared wavelengths.

Another embodiment provides a method of manufacturing a device comprising: providing a first filter of a first color configured for only letting through wavelengths of said first color and infrared; arranging the first filter vertically in line with at least one first pixel and at least partially in line with a second pixel; wherein the first pixel has a single junction and the second pixel comprises a heterojunction based on quantum dots; interposing an optical element between the first filter and the second pixel; wherein the first filter and the optical element are configured so that the first pixel receives wavelengths of said first color and the second pixel only receives infrared wavelengths.

According to an embodiment, the device comprises: at least one third pixel having a single junction; at least one second filter of a second color configured for only letting through wavelengths of said second color and infrared, said at least one second filter arranged vertically in line with the third pixel and at least partially in line with the second pixel; wherein the optical element is interposed between the second filter and the second pixel; wherein the second filter and the optical element are configured so that the third pixel receives wavelengths of said second color and the second pixel only receives infrared wavelengths.

According to an embodiment, the heterojunction is sensitive to infrared wavelengths.

According to an embodiment, said single junction(s) are sensitive to wavelengths of the visible domain.

According to an embodiment, the optical element comprises an interference mirror configured to let through towards the second pixel infrared wavelengths, and to reflect visible wavelengths.

According to an embodiment, the optical element comprises an optical steering element configured to direct infrared wavelengths towards the second pixel, and visible wavelengths towards a pixel different from the second pixel.

According to an embodiment, said interference mirror is interposed between the second pixel and the optical steering element.

According to an embodiment, the optical steering element comprises a meta surface.

According to an embodiment, said meta surface comprises metal oxide pillars in a matrix comprising a nitride.

According to an embodiment, at least two of the pixels are electrically insulated from each other by an insulated conductive wall configured to be coupled to a voltage rail receiving a negative voltage.

According to an embodiment, the second pixel comprises a first doped region of a first conductivity type, the first doped region comprising a first layer and a second layer forming said heterojunction, the first layer being made of a semiconductor material and the second layer comprising said quantum dots.

According to an embodiment, the second pixel comprises a second doped region of a second type of conductivity, the second doped region being in contact with the second layer.

According to an embodiment, the first layer is laterally surrounded by said insulated conductive wall, the dopant concentration of the first layer being higher than that of the second layer.

According to an embodiment, the first pixel and/or the third pixel comprises a first region with a first doped layer of the first conductivity type, and a second doped region of the second conductivity type.

According to an embodiment, the first doped layer of the first region of the second pixel comprises a notch, the second layer being at least partly formed in said notch.

An embodiment provides a method of using the above-described device, comprising the acquisition of images in the visible range from at least the first pixel and in infrared from the second pixel.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows an example of an electronic device;

FIG. 2 schematically shows an embodiment of an electronic device;

FIG. 3 shows a cross-section view along a plane A-A of the device of FIG. 2;

FIG. 4 shows a cross-section view along plane A-A of another embodiment of the device of FIG. 2; and

FIG. 5 shows a cross-section view along plane A-A of another embodiment of the device of FIG. 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

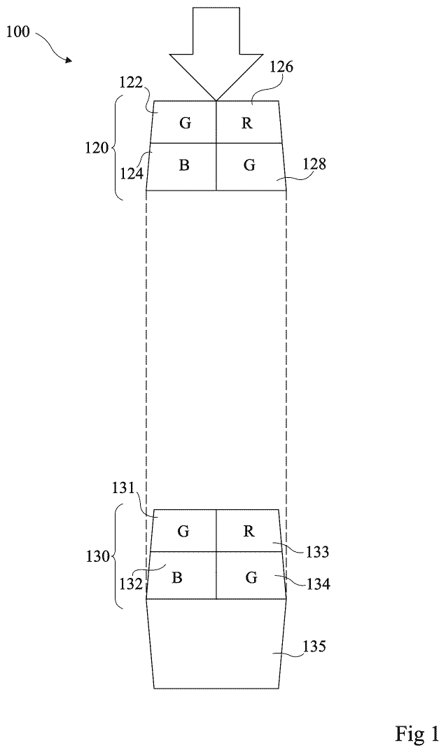

FIG. 1 schematically shows an example of an electronic device 100.

In the shown example, device 100 comprises, for example, a plurality of color filters 122(G), 124(B), 126(R), 128(G). In an example, each of these filters 122, 124, 126, 128 only lets through the visible wavelengths associated with this color. For example, filter 122 lets through green (G) color wavelengths only, filter 124 lets through blue (B) color wavelengths only, filter 126 lets through red (R) color wavelengths only, and filter 128 lets through green (G) color wavelengths only. In other words, reference to “lets through” is understood to mean that the wavelengths which originate from a filter of a given color are, for example, by more than 50%, preferably by more than 80%, and even more preferably by more than 90%, within the spectrum associated with this color. In an example, even though filters 122, 124, 126, 128 enable to select, in the visible range, the wavelengths associated with their color in the visible range, they let through a majority of the incident infrared radiation.

These filters 122, 124, 126, 128 are, for example, arranged in a Bayer matrix format.

In an example, device 100 comprises a plurality of, or even tens, or hundreds, or preferably thousands of assemblies 120 formed by the four filters.

In another example, each assembly 120 comprises a single one of the filters, or only two filters of different color, or three filters that may or not be of different colors.

In accordance with the description herein, it will be understood that the green (G) color comprises wavelengths approximately in the range from 520 to 565 nm, the red (R) color comprises wavelengths approximately in the range from 625 to 740 nm, and the blue (B) color comprises wavelengths approximately in the range from 450 to 500 nm. Other filters associated with other visible colors are also possible, such as yellow-colored, orange-colored, cyan-colored, indigo-colored, or also violet-colored filters.

In accordance with the description herein, it will be understood that the infrared range comprises, for example, short-wave infrared (SWIR) wavelengths. In other words, as described herein, infrared (IR) comprises, for example, wavelengths greater than or equal to 1 μm, for example 1.1 μm or 1.130 μm. Near infrared (NIR) comprises, for example, wavelengths extending between 780 and 1 μm, and these wavelengths may also be considered in the following examples, for example by modifying the quantum dot size or nature.

In the shown example, device 100 further comprises an array 130 of four pixels 131 (G), 132(B), 133(R), 134(G) arranged vertically in line with assembly 120. Each of these pixels 131(G), 132(B), 133(R), 134(G) comprises, for example, a single junction formed, for example, in a semiconductor substrate 135 such as silicon, and is configured to transform the visible wavelengths that it receives into electrical charges. The processing of these charges, by a circuit not shown, gives rise to a signal which is then processed to form images, for example.

In the shown example, each pixel 131, 132, 133, 134 is arranged vertically in line with one of the filters of assembly 120. For example, pixel 131 is arranged vertically in line with filter 122, pixel 132 is arranged vertically in line with filter 124, pixel 133 is arranged vertically in line with filter 126, and pixel 134 is arranged vertically in line with filter 128.

In an example, device 100 comprises a plurality of, or even tens, or hundreds, or preferably thousands of pixel arrays 130 formed by the four pixels 131, 132, 133, 134.

In another example, each array 130 comprises a single one of the pixels, or only two pixels, or three pixels.

The fact of using silicon single junctions for the pixels, however, does not enable to capture infrared spectrum data for the same images. Such data can be advantageous, for example, for time-of-flight determination or distance calculation.

It is possible to use pixels using quantum dots sensitive to infrared and to the visible range to capture both visible and infrared wavelengths of a same image. However, the efficiency of these devices is limited in the visible range by the low bandgap value and a high density of defects.

Other solutions, referred to as above interconnects (ABIC), are complex to implement with the increasingly high resolutions required, and they also suffer from a loss of performance due to dark current and to noise.

To overcome these disadvantages, the described embodiments provide a device comprising: at least one first pixel having a single junction; at least one second pixel comprising a heterojunction based on quantum dots; at least one first filter of a first color configured to only let through wavelengths of said first color and infrared, with the first filter arranged vertically in line with the first pixel and at least partially in line with the second pixel; and an optical element interposed between the first filter and the second pixel; wherein the first filter and the optical element are configured so that the first pixel receives wavelengths of said first color and the second pixel only receives infrared wavelengths.

This solution enables to use a standard Bayer grid, and thus does not require a complex development on image reconstruction.

The fact of separating visible wavelengths from infrared wavelengths is simpler than to implement than the fact of separating visible wavelengths from one another.

This solution further enables to improve the external quantum efficiency (EQE) for each wavelength channel.

The wavelength rejection is also improved by the separation of visible and infrared wavelengths.

The fact for the quantum dots not to be used in all pixels enables not to have an infrared absorption in pixels having a single junction, which ultimately enables to improve the rejection between visible and infrared wavelengths in each channel.

This architecture further enables to limit dark currents, since there is no charge injection by electrodes.

Noise is also decreased, while allowing a simple manufacturing.

This solution also enables to limit crosstalk between pixels due to the physical separation between visible pixels and infrared pixels.

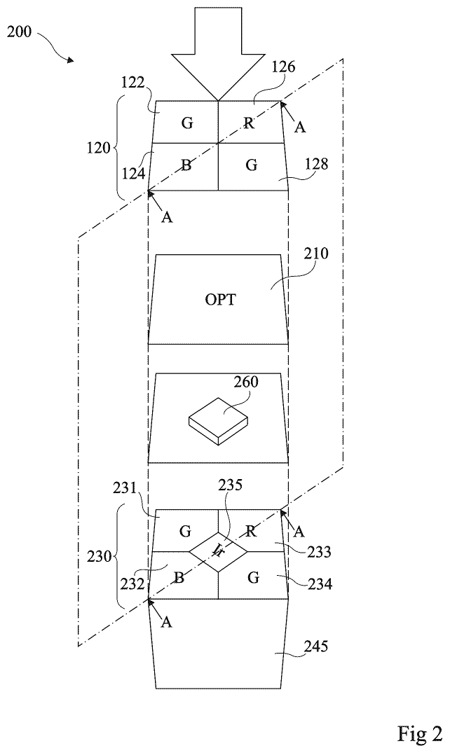

FIG. 2 schematically shows an embodiment of an electronic device 200.

In the shown example, device 200 comprises an optical assembly similar to assembly 120.

In the shown example, device 200 further comprises an array 230 of five pixels 231 (G), 232(B), 233(R), 234(G), and 235(Ir) arranged vertically in line with assembly 120. Each of the pixels 231(G), 232(B), 233(R), 234(G) of array 230 comprises, for example, a single junction formed in a semiconductor substrate 245, such as silicon, and is configured to transform the visible wavelengths that it receives into electrical charges.

Pixel 235 comprises, for example, a heterojunction formed from a layer 260, having quantum dots, arranged in contact with a semiconductor structure, for example based on silicon, for example a region of a bulk semiconductor substrate. Thus, the term “heterojunction” in the this context is understood to mean a junction between a layer comprising quantum dots and one of: i) a layer of semiconductor material for a substrate, or ii) a region of a bulk semiconductor substrate. This semiconductor structure is, for example, also present in pixels 231, 232, 233, 234, which limits design costs.

For example, layer 260 is arranged only in pixel 235 and does not project above the pixels 231, 232, 233, and 234 of the visible domain (i.e., those sensitive to the range of wavelengths for visible light). This enables to improve the optical rejection between pixels 231, 232, 233, and 234 and pixel 235. The positioning of layer 260 is, for example, performed by etching of a layer containing the quantum dots or by local deposition.

A quantum dot or semiconductor nanoparticle is a nanoscopic material structure which generates electron-hole pairs in the presence of the incidence of photons on the nanoscopic material structure.

A quantum dot comprises a semiconductor core. A quantum dot may also comprise a shell, preferably made of a semiconductor material, surrounding the core so as to protect and to passivate the core. A quantum dot further comprises ligands, organic aliphatic compounds, metal-organic or inorganic molecules which extend from the shell and passivate, protect, and functionalize the semiconductor surface.

The composition of a quantum dot can be selected from the following materials. The core is for example made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si. The shell is, for example, made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si.

Preferably, all the core dimensions are smaller than 20 nm, for example in the range from 2 to 15 nm. In particular, the diameter of each quantum dot is preferably in the range from 2 to 15 nm. By diameter, this means the diameter of the smallest sphere in which the quantum dot can be inscribed.

It is possible to select a size and a dimension of quantum dots capable of absorbing, with a significant absorption, any wavelength within a wide range of wavelengths. For example, it is possible to find a size and a dimension of quantum dots having an operating wavelength greater than 1 μm, for example in the range from 1 μm to 3 μm, which includes near infrared and short-wave infrared. For example, layer 260 comprises quantum dots made of InAs, of PbS, of HgTe, or of PbSe, with a radius smaller than 10 nm, for example, to obtain an absorption peak related to quantum confinement in short-wave infrared, for example, 1,130 nm or 1,360 nm.

Layer 260 has, for example, a thickness in the range from 100 nm to 500 nm.

In the shown example, pixel 235 is arranged at the center of array 230 so that it is surrounded by pixels 231, 232, 233, 234. As compared with the array 130 of FIG. 1, the area for receiving the light incident on each of pixels 231, 232, 233, and 234 is decreased by part of the footprint of central pixel 235.

In the shown example, pixel 233 is separated from pixel 232 via pixel 235, and pixel 231 is separated from pixel 234 via pixel 235. This enables to improve the crosstalk performance.

In an example, the surface area of array 230 is similar to that of array 130.

In the shown example, filter 122 is arranged vertically in line with pixel 231 and at least partially vertically in line with pixel 235; filter 126 is arranged vertically in line with pixel 233 and at least partially vertically in line with pixel 235; filter 128 is arranged vertically in line with pixel 234 and at least partially vertically in line with pixel 235; and filter 124 is arranged vertically in line with pixel 232 and at least partially vertically in line with pixel 235.

In an example, device 200 comprises a plurality of, or even tens, or hundreds, or preferably thousands of pixel arrays 230.

In an example, not shown, each array 230 comprises a single one of pixels 231, 232, 233, or 234 and pixel 235. In this case, only one of filters 122, 124, 126, or 128 is present in the associated assembly 120.

In an example not shown, each array 230 comprises only two of pixels 231, 232, 233, or 234 and pixel 235. In this case, only two of filters 122, 124, 126, or 128 are present in the associated assembly 120.

In an example, not shown, each array 230 comprises only three of pixels 231, 232, 233, or 234 and pixel 235. In this case, only three of filters 122, 124, 126, or 128 are present in the associated assembly 120.

In the shown example, an optical element 210 (OPT) is interposed between at least one of the filters 122, 124, 126, 128 of assembly 120 and at least one of the pixels 231, 232, 233, 234, 235 of array 230. In other words, optical element 210 is arranged vertically in line with at least one region of one of the filters 122, 124, 126, 128 of assembly 120, and between a plane in which the filters are formed and a plane of layer 260, so as to cover at least pixel 235.

The filter(s) of assembly 120 and optical element 210 are configured so that pixel(s) 231, 232, 233, 234 receive wavelengths of the color of the associated filter but also infrared, and so that pixel 235 receives only infrared wavelengths.

In an example, optical element 210 comprises an interference mirror, or Bragg mirror, configured to let through towards pixel 235 infrared wavelengths, and to reflect visible wavelengths.

In an example, the interference mirror is formed of a stack of layers of SiON and of amorphous silicon a-Si, for example having respective thicknesses of 125 nm and 50 nm.

The interference mirror, or Bragg mirror, enables to improve the rejection of visible wavelengths which might pollute the signal generated by the pixel dedicated to infrared.

In another example, optical element 210 comprises an optical steering element configured to direct infrared wavelengths towards pixel 235, and visible wavelengths towards one of pixels 231, 232, 233, 234. In other words, the optical steering element is configured, for example, to deflect with a certain angle wavelengths of the visible range originating from filters 122, 124, 126, or 128 and deflect with another angle wavelengths of the infrared range originating from filters 122, 124, 126, or 128. Thereby, infrared wavelengths are directed towards pixel 235, while visible wavelengths are directed towards at least one of pixels 231, 232, 233, 234.

In an example, optical steering element 210 comprises a meta surface. This meta surface comprises, for example, pillars or reliefs made of a material having a high optical (or refractive) index, for example above 2, for example of metal oxide, for example of TiO2. In an example, these pillars are arranged in an array of lower optical index, for example a nitride, for example a silicon nitride.

The arrangement and the shape of the pillars or of the reliefs of high optical index can be simulated to obtain the different deflections according to the desired wavelengths.

The implementation of the optical steering element enables to improve the external quantum efficiency of each channel, since this compensates for the size decrease of pixels 231, 232, 233, 234 for the integration of pixel 235.

In an example, optical element 210 comprises an interference mirror, or a Bragg mirror, and the optical steering element where the interference mirror is interposed between pixel 235 and the optical steering element.

In the shown example, a cross-section plane A-A vertically runs through filters 124 and 126, optical element 210, layer 260, as well as pixels 232, 233, and 235.

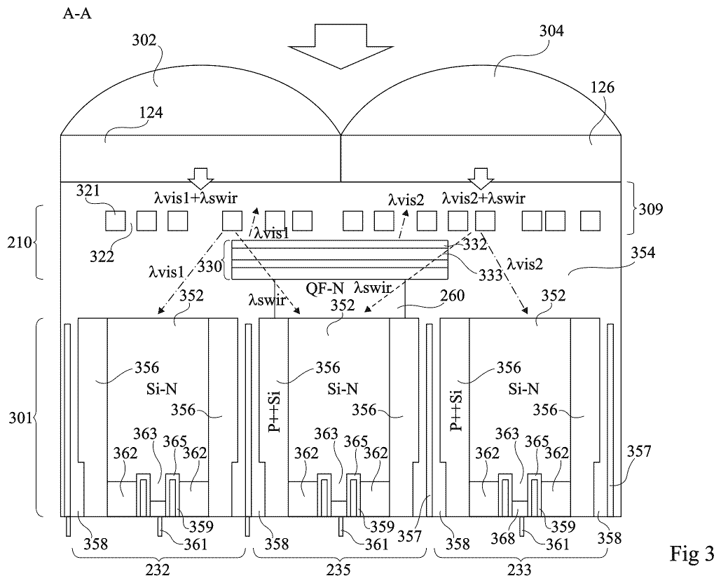

FIG. 3 shows a cross-section view along plane A-A of an embodiment of the device 200 of FIG. 2.

In the shown example, pixels 232, 235, and 233 are respectively arranged next to one another. Pixel 235 is arranged between pixel 232 and pixel 233, this enables to avoid the crosstalk phenomenon.

In this example, pixel 232 is arranged vertically in line with filter 124, pixel 235 is arranged vertically in line with a portion of filter 124 and vertically in line with a portion of filter 126, and pixel 233 is arranged vertically in line with filter 126.

In the shown example, optical element 210 is interposed between the plane formed by filters 124 and 126 and the plane formed by a surface of pixels 232, 233, and 235 facing the filters.

In the shown example, optical element 210 comprises optical steering element 309 as well as interference mirror 330. In this example, optical steering element 309 extends below filters 124 and 126 so as to be able to differentially deflect the visible wavelengths λvis1, λvis2 with respect to the infrared wavelengths λswir. Thus, pixel 232 receives visible wavelengths λvis1 of the color of filter 124, pixel 233 receives visible wavelengths λvis2 of the color of filter 126, and pixel 235 receives infrared wavelengths λswir originating from optical element 210. Optical steering element 309 comprises pillars 321 of high optical index arranged in an array 322 of lower optical index. It is also possible for the optical index of pillars 321 and for their array 322 to be reversed.

In the shown example, optical element 210 further comprises interference mirror 330. In this example, the interference mirror comprises a double stack of two layers 332 and 333. Layers 332 are, for example layers having a thickness of approximately 125 nm made of SiON, and layers 333 are, for example, layers having a thickness of approximately 50 nm made of amorphous silicon. The purpose of this interference mirror is to allow the passage of infrared wavelengths while rejecting, that is, for example by reflecting, visible wavelengths λvis1 or λvis2. The number of layers 332 and 333 may be greater than 2, for example in the order of ten. The interference mirror is arranged, for example, so as to horizontally only cover pixel 235 and not to cover pixels 232 and 233.

In the shown example, the interference mirror is laterally surrounded, for example, by an insulator 354, which is, for example, different from an insulator 322 surrounding pillars 321. This insulator is, for example, a silicon oxide.

In the example of FIG. 3, the layer 260 which comprises the quantum dots (QF-N) is located vertically between interference mirror 330 and a structure 301 of pixel 235, and horizontally so as to project slightly beyond structure 301. Layer 260 is laterally surrounded for example by insulator 354.

In the shown example, the pixels dedicated to the visible range 232 and 233 comprise a structure 301 similar to that of pixel 235.

Structure 301 is formed in a semiconductor substrate, for example silicon. Structure 301 comprises a first layer 352 (Si—N) of a first conductivity type, for example of type N. In an example, the thickness of layer 352 is from approximately 5 to 10 μm.

In an example, the first layer 352 of pixel 232 receives the visible wavelengths λvis1 of the color of filter 124, and the first layer 352 of pixel 233 receives the visible wavelengths λvis2 of the color of filter 126.

One side of the first layer 352 of the structure 301 of pixel 235, facing the optical filters, is in contact with quantum dot layer 260. This forms the heterojunction of pixel 235. Layer 260 comprises, for example, quantum dots of the same conductivity type as layer 352, for example of type N. Layer 260 forms the photosensitive layer of the created photodiode. In pixel 235, the heterojunction receives infrared wavelengths λswir originating from filters 124, 126 and from optical element 210 and transforms them into electron-hole pairs.

In an example, adjacent pixels 232, 233, 235 are electrically insulated from one another by a conductive wall 357 insulated with an electrical insulator 358 and configured to be coupled to a voltage rail receiving a negative voltage, for example −1 V. This further enables to deplete the first layer 352 of the different pixels and to create pinned diodes absorbing the photogenerated electrons.

In the shown example, pixel 235 comprises a region 356 (P++Si) doped according to a second conductivity type, for example P, which is in contact at least partially with first layer 352. This region 356 is further arranged between walls 357, 358 and first layer 352. In an example, the dopant concentration of region 356 is high (P++), for example 10¹⁸ at.cm⁻³. Region 356, in the case of pixel 235, advantageously enables to adapt the bandgap difference between layer 260 and the first layer 352 of this pixel so as to allow the draining off of the holes photogenerated in layer 260. The negatively-biased walls and region 356 heavily doped with the second conductivity type create an electric field enabling to improve the field effect. The region 356 thus arranged further enables to avoid the influence of dark currents. In an example, region 356 is optional or of lower dopant concentration.

In the shown example, the pixels 232 and 233 dedicated to the visible range further comprise region 356 arranged similarly to pixel 235 except that it is not in contact with a quantum dot layer but with the insulator covering the surface of the first layer 352 of the respective pixel. For these pixels dedicated to the visible range, region 356 is optional, although it is advantageous to amplify silicon depletion and limit dark current.

In the shown example, each pixel 232, 233, 235 comprises a sense node 361 coupled, preferably connected, to a structure forming a vertical MOS-type transistor, for example cylindrical. This transistor is formed by an area 368, of the first conductivity type, for example type N, with a high dopant concentration, in contact with sense node 361, and configured to form a channel. This area 368 is surrounded by a control gate, for example vertically cylindrical, formed by a conductive core 359, for example made of polysilicon, which is insulated from area 368 by an insulator 365, for example a silicon oxide. An area 363, which is a portion of layer 352, is arranged in contact with area 368 while being surrounded by insulator 365. An area 362, doped according to the second conductivity type, for example couples the region 356 of each pixel to control gate 359, 365. This area 362 enables to electrostatically insulate the transistors of the pixel, for example, the amplifiers, transfer transistors, and to control the potential of layer 356 to drain off the photogenerated electrons. By negatively biasing the control gate, the channel is closed to store the photogenerated electrons, and by positively biasing it, the electrons are drained off to form the signal of the respective pixel. Pixels 232, 233 thus generate a signal originating from visible photons linked to the color of their respective filter, and pixel 235 generates a signal originating from the infrared photons passing through filters 124 and 126.

In the shown example, color filters 124 and 126 are topped by microlenses respectively 302 and 304. These microlenses enable to focus the incident light (shown as an arrow in FIG. 3) onto the associated filters and pixels.

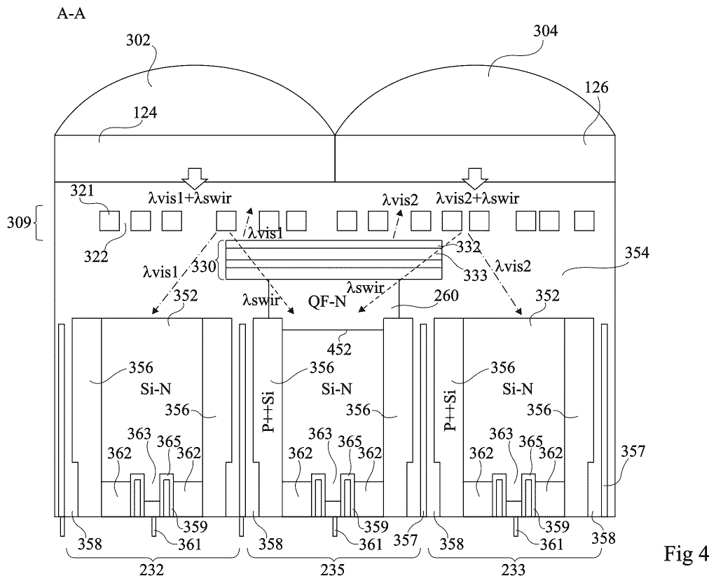

FIG. 4 shows a cross-section view of another embodiment of the device 200 of FIG. 2.

The example of FIG. 4 is similar to that of FIG. 3, except that layer 352 of pixel 235 comprises a notch 452 in which is arranged a portion of layer 260. This enables to increase the field effect. This notch 452 is, for example, obtained by etching of layer 352.

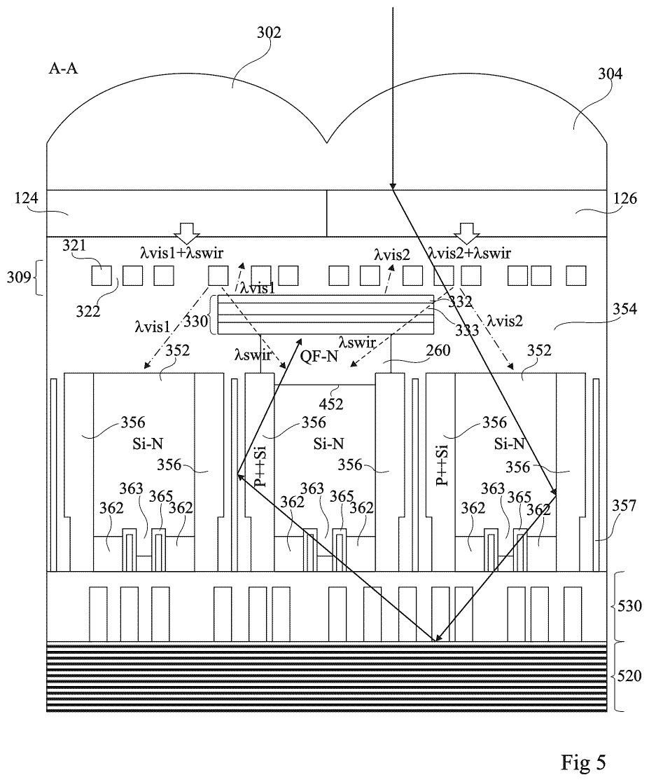

FIG. 5 shows a cross-section view along plane A-A of another embodiment of the device of FIG. 2.

The shown example is similar to that of FIG. 4 except that an optical guiding and reflection element 530 is optionally arranged between the structures 301 of the photodiode and a metal interconnection layer 520 which is coupled, for example, to the different pixels. The optical guiding and reflection element 530 is arranged in such a way as to enable to redirect the infrared wavelengths passing through pixels 232 and 233 towards pixel 235 so that they are absorbed by photosensitive layer 260 and thus increase the quantum efficiency of pixel 235. In the shown example, the infrared wavelengths not absorbed by the pixels dedicated to the visible range reflect on the interconnects (illustrated by arrows in the drawing), to be redirected towards the pixel 235 dedicated to infrared absorption. In an example, optical guiding and reflection element 530 comprises one or a plurality of reflective meta-surfaces.

Device 200 may be used, for example, in smartphones, in systems using cameras, in sensors sensitive to visible light and for distance measurement, for face or shape detection, or also in the automotive industry.

Various embodiments and variants have been described. Those skilled in the art will understand that certain features of these various embodiments and variants could be combined, and other variants will become apparent to those skilled in the art. In particular, although FIGS. 3 and 4 show optical element 210 as comprising both optical steering element 309 and interference mirror 330, it is also possible for optical element 210 to comprise optical steering element 309 only or interference mirror 330 only. In the case where optical element 210 comprises interference mirror 330 only, the pixels dedicated to visible light can receive infrared wavelengths. However, these pixels being based on a silicon single junction, for example, the latter is virtually insensitive to these infrared wavelengths.

Finally, the practical implementation of the described embodiments and variants is within the abilities of those skilled in the art, based on the functional indications given above. In particular, with regard to the examples of FIGS. 3 and 4, those skilled in the art may also implement their teachings with arrays 230 of pixels only formed of a single pixel dedicated to visible wavelengths and of a pixel dedicated to infrared. In this case, a single visible color filter may be envisaged per assembly 120. Those skilled in the art may also implement arrays 230 of pixels only formed of two pixels dedicated to visible wavelengths and of one pixel dedicated to infrared. In this case, two different visible color filters can be envisaged per assembly 120. Those skilled in the art may also implement arrays 230 of pixel only formed of three pixels dedicated to visible wavelengths and of one pixel dedicated to infrared. In this case, two or three different visible color filters may be envisaged per assembly 120.

1. An electronic device, comprising:
at least one first pixel having a single junction;
at least one second pixel comprising a heterojunction formed by a semiconductor substrate layer in contact with a quantum dot layer;
at least one first filter of a first color configured for only letting through wavelengths of said first color and infrared, said at least one first filter arranged vertically in line with the at least one first pixel, and at least partially vertically in line with the at least one second pixel; and
an optical element interposed between the at least one first filter and the at least one second pixel;
wherein the at least one first filter and the optical element are configured so that the at least one first pixel receives wavelengths of said first color and the at least one second pixel only receives infrared wavelengths.

2. The device according to claim 1, further comprising:
at least one third pixel having a single junction;
at least one second filter of a second color configured for only letting through wavelengths of said second color and infrared, said at least one second filter arranged vertically in line with the at least one third pixel and at least partially vertically in line with the at least one second pixel;
wherein the optical element is interposed between the at least one second filter and the at least one second pixel;
wherein the at least one second filter and the optical element are configured so that the at least one third pixel receives wavelengths of said second color and the at least one second pixel only receives infrared wavelengths.

3. The device according to claim 1, wherein each of the at least one first pixel and the at least one third pixel comprises a first region with a first doped layer of a first conductivity type and a second doped region of a second conductivity type.

4. The device according to claim 1, wherein the heterojunction is sensitive to light having infrared wavelengths.

5. The device according to claim 4, wherein said single junction is sensitive to light having visible wavelengths.

6. The device according to claim 1, wherein the optical element comprises an interference mirror configured to let light of infrared wavelengths through towards the at least one second pixel and to reflect light of visible wavelengths.

7. The device according to claim 1, wherein the optical element comprises an optical steering element configured to direct light of infrared wavelengths towards the at least one second pixel, and direct light of visible wavelengths towards a pixel different from the at least one second pixel.

8. The device according to claim 7, wherein the optical element further comprises an interference mirror configured to let light of infrared wavelengths through towards the at least one second pixel and to reflect light of visible wavelengths, and wherein said interference mirror is interposed between the at least one second pixel and the optical steering element.

9. The device according to claim 7, wherein the optical steering element comprises a meta surface.

10. The device according to claim 9, wherein said meta surface comprises metal oxide pillars in a matrix comprising a nitride.

11. The device according to claim 1, further comprising an insulated conductive wall configured to be coupled to a voltage rail receiving a negative voltage and positioned to electrically insulate pixels from each other.

12. The device according to claim 1, wherein the at least one second pixel comprises a first doped region of a first conductivity type, the first doped region comprising said semiconductor substrate layer in contact with the quantum dot layer.

13. The device according to claim 12, wherein the at least one second pixel further comprises a second doped region of a second conductivity type, the second doped region being in contact with the second layer.

14. The device according to claim 12, wherein the first layer is laterally surrounded by an insulated conductive wall configured to be coupled to a voltage rail receiving a negative voltage, and wherein a dopant concentration of the first layer is higher than a dopant concentration of the second layer.

15. The device according to claim 12, wherein the first layer of the first doped region of the at least one second pixel comprises a notch, and wherein the second layer is at least partly formed in said notch.

16. The device according to claim 1, wherein the at least one first pixel comprises a first doped layer of a first conductivity type and a second doped region of a second conductivity type.

17. An electronic device, comprising:
at least one first pixel having a single junction;
at least one second pixel comprising a heterojunction based on quantum dots formed by a first region in a semiconductor substrate in contact with a quantum dot layer;
at least one first filter of a first color configured for only letting through wavelengths of said first color and infrared, said at least one first filter arranged vertically in line with the at least one first pixel, and at least partially vertically in line with the at least one second pixel; and
an optical element interposed between the at least one first filter and the at least one second pixel;
wherein the at least one first filter and the optical element are configured so that the at least one first pixel receives wavelengths of said first color and the at least one second pixel only receives infrared wavelengths.

18. An electronic device, comprising:
a plurality of pixels that are laterally insulated from each other;
wherein each pixel of said plurality of pixels includes a first substrate region doped with a first conductivity type;
wherein the plurality of pixels includes first pixels having a single junction and second pixels comprising a heterojunction based on quantum dots;
wherein said heterojunction based on quantum dots for each of the second pixels comprises a quantum dot layer in contact with an upper surface of the first substrate region;
at least one first filter of a first color configured for only letting through wavelengths of said first color and infrared, said at least one first filter arranged vertically in line with the first pixel, and at least partially vertically in line with the second pixel; and
an optical element interposed between the at least one first filter and the second pixel;
wherein the at least one first filter and the optical element are configured so that the first pixel receives wavelengths of said first color and the second pixel only receives infrared wavelengths.

19. The device of claim 18, wherein each pixel of said plurality of pixels further includes a second substrate region doped with a second conductivity type positioned between the first substrate region and an insulating wall providing lateral insulation between adjacent pixels of the plurality of pixels, and wherein the quantum dot layer is also in contact with an upper surface of the second substrate region.
